(19) United States
(12) Patent Application Publication
(10) Pub. No.: US 2026/0351837 A1
(43) Pub. Date: Nov. 5, 2026

(54) CHIP-TO-CHIP HIGH-SPEED I/O LINKS ENABLED BY REMOVABLE WAVEGUIDE INTERCONNECT BRIDGES

(71) Applicant: Intel Corporation, Santa Clara, CA (US)

(72) Inventors: Tae Young YANG, Portland, OR (US); Tolga ACIKALIN, San Jose, CA (US); Kenneth P. FOUST, Beaverton, OR (US); Shuhei YAMADA, Vancouver, WA (US); Stephen MOREIN, San Jose, CA (US); Harry SKINNER, Beaverton, OR (US)

(21) Appl. No.: 19/488,641

(22) PCT Filed: Dec. 21, 2023
(86) PCT No.: PCT/US2023/085279

§ 371 Date: Nov. 28, 2025

(51) Int. Cl. H01Q 1/22; H01P 3/00; H01Q 15/16; H10W 44/20

(52) U.S. Cl. CPC H01Q 1/2283; H01P 3/00; H01Q 15/16; H10W 44/20

(57) ABSTRACT

A wireless chip-to-chip device with removable waveguide includes a first substrate comprising a first antenna; a second substrate comprising a second antenna; and the removable waveguide, which includes a waveguide that is configured to be removably positioned between the first substrate and the second substrate and to direct a radio signal from the first antenna to the second antenna.

### TECHNICAL FIELD

Various aspects of this disclosure generally relate to a removable waveguide for wireless, chip-to-chip communication.

### BACKGROUND

Conventional hardware accelerators may include an Open-computer-project Accelerator Module (OAM) architecture, which in some circumstances may be plugged into a Universal Base Board (UBB), such as through Mezzanine connectors. The OAM form factor facilitates scalability across accelerators by simplifying the system solution when interconnecting wired communication links among chips, compared to, for example, a classic peripheral component interconnect express (PCIe) add-in card form factor. The scalability of such hardware accelerators toward a Zettascale computing system is, however, limited, at least by the requirement for a high-bandwidth interconnect.

At the same time, there is increased demand for higher aggregated data rates for interconnects. When considering a conventional copper-based signal-escape approach (such as through a chip package, a printed circuit board (PCB), silicon, or any combination thereof), this increased demand for higher aggregated data rates results in increased cost and power consumption. Moreover, such demand brings additional challenges, such as corresponding signal integrity degradation and higher latency due to the increased signal path length through the Plated Through Hole (PTH) vias, balls, connectors, and package/PCB traces. This may necessitate additional filter taps for processing of the resulting signal, such as for signal equalization and cross talk mitigation. Such additional filter tap also result in higher power consumption, which may be undesirable.

In some implementations, these problems have been at least partially remedied by the implementation of a wireless waveguide interconnect bridge (WIB), for communication between chips within a multi-chip package. Such use of the WIB can reduce the signal path length between OAMs, thereby improving latency. Moreover, since such WIBs reduce the need for wired interconnects, they can reduce signal integrity degradation and cross-talk. In such configurations, a radiofrequency integrated circuit (RFIC) and coupler chiplet can be placed on the top side of the package edges, with one or more WIBs between adjacent OAMs.

In some configurations, it may be desirable for such WIBs to be removable; however, this raises several practical technical challenges, such as (1) a vertically-polarized ultra-wideband (UWB) coupler design, (2) signal leakage/isolation between the WIB and the top surface of coupler chip, (3) misalignment between the coupler and the WIB arrays, and (4) vertical and horizontal scalability for data aggregation.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts an exemplary multichip configuration with chip-to-chip connections via a waveguide;

FIG. 2 depicts an optional aggregated multiple channel arrangement with a waveguide array;

FIG. 3 depicts a cross-section of a waveguide of FIG. 2

FIG. 4 depicts a glass-based stack-up for a coupler and WIB design;

FIG. 5 depicts a 3D View of geometry, channel, and port definitions for the multichip stack with removable waveguide;

FIG. 6 depicts layers of a substrate:

FIG. 7 depicts a 4-channel design example;

FIG. 8 depicts S-parameters S12-S82 for a simulation with Port 2 excitation;

FIG. 9 depicts S-parameters for five waveguide lengths;

FIG. 10 depicts a group delay for a 1 mm and a 20 mm waveguide;

FIG. 11 depicts a coupler and WIB design;

FIG. 12 depicts S-Parameters for a simulation;

FIG. 13 depicts a flat group delay for the device of FIG. 11;

FIG. 14 depicts a chip-to-chip waveguide interconnection with a resulting gap;

FIG. 15 depicts vector electromagnetic fields on a good electric conductor (GEC);

FIG. 16 depicts vector electromagnetic fields on a good magnetic conductor (GMC);

FIG. 17 depicts an electromagnetic field leakage reduction structure referred to herein as the magic wall;

FIG. 18 depicts a simulated performance of a glass-based engineered material deign;

FIG. 19 depicts a good magnetic conductor (GMC) for use in the magic wall of FIG. 17;

FIG. 20 depicts a chip to chip connection with a removable waveguide module;

FIG. 21 depicts a WIB having linear tapering at its waveguide opening;

FIG. 22 depicts a WIB having non-linear (e.g. rounded) tapering;

FIG. 23 depicts electromagnetic leakage in vertically stacked chiplets;

FIG. 24 depicts a waveguide module with waveguides of differing lengths;

FIG. 25 depicts a stacked-chip interconnection using vertically-stacked removable waveguides;

FIG. 26 depicts a first configuration for horizontal scalability with a zig-zig alignment; and

FIG. 27 depicts an alternative in which the waveguides are implemented with a trapezoidal shape.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [. . . ] , etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [. . . ] , etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

Throughout this disclosure, the words “chip” and “chiplet” are used. Although a “chiplet” is often used to reference to a small integrated circuit with a particularized function, it is recognized that the definition of a chip and a chiplet may be understood differently in different contexts, in different branches, by different manufactures, and the like. Moreover, the line of demarcation between a chip and a chiplet may be unclear in some contexts. In light of this, it is expressly acknowledged that the structures, configurations and/or functions ascribed herein to a chiplet, with respect to the use of a removeable waveguide, may be performed or exhibited by a chip; similarly, any structures, configurations and/or functions ascribed herein to a chip, with respect to the use of the removeable waveguide, may be performed or exhibited by a chiplet. Thus, any aspect of this disclosure that is described with respect to a chiplet may be applied to a chip, and vice versa.

Metamaterials in general may be artificial materials that are designed and used in consideration with one or more specific properties, such that certain properties may be manipulated to provide or mimic the properties that are not found in naturally occurring materials. Such artificial materials may include engineered materials and/or metamaterials. In its broader representation, engineered materials can be any type of material that is intentionally designed and fabricated for a specific purpose. On the other hand, metamaterials are specifically designed to interact with electromagnetic waves, such as radio waves, microwaves, and light, in unusual ways. Metamaterials may usually include metallic or dielectric structures that are smaller than the wavelength of target electromagnetic waves, and they can be engineered to have negative refractive index, superconductivity, or other unusual properties.

In accordance with various aspects provided in this disclosure, interference reducing and/or blocking methods are provided via use of metamaterials. A metamaterial may form a surface that does not allow electric fields incident to the normal direction of the surface from a side to pass to the other side, at least partially. The metamaterial as disclosed herein may be a good magnetic conductor (GMC). The surface may optionally have an effective negative permeability, and accordingly may also be referred to as a “metasurface”. The metamaterial's surface(s) may create an invisible vertical wall (e.g. when metamaterial, such as AMC structure lies in the horizontal plane, i.e. ground plane and metallic plate lie in the horizontal plane) without the physical form. The formed invisible vertical wall may reflect the incident electric fields, or may absorb by providing a “cloaking” effect.

Some aspects provided herein may relate to the use of metamaterials in applications that require electromagnetic interference/radio frequency interference (EMI/RFI) shielding and/or improve isolation between electromagnetic radiators, which can be exemplified via use of a connector for data communication within this disclosure. Some aspects provided herein may relate to the use of metamaterials in wireless chip-to-chip communication. In some aspects, at least some of chips in exemplified structures may include radio frequency integrated circuits (RFICs). Through aspects provided herein, RFICs may be shielded against EMI/RFI.

As stated above, the use of removable/pluggable waveguides for wireless signal-escaping interconnect between open-computer-project accelerator modules (OAMs) presents several additional challenges. In the following, a new WIB module will be described. This WIB may optionally be used with various horizontal glass-based wireless I/O (WIO) approaches. The resulting WIB can operate with air and/or immersion/liquid cooling systems. As such, the WIB mitigates the above-referenced scalability challenges related to Zettascale computing that results from the high-bandwidth interconnect requirements in OAM-based hardware accelerators.

As described above, conventional wired signal-escaping interconnects through package, PCB, and/or silicon bridges result in signal integrity degradation and higher latency due to the increased signal path length through plated through hole (PTH) vias, balls, connectors, and package/PCB traces. As such, they require additional filter taps for equalization and cross talk mitigation, which then results in higher power consumption and may thus be undesirable. Stated differently, the conventional approaching of using wired signal-escaping interconnects cannot keep up with the bandwidth/throughput demands of hardware accelerators.

In light of this problem, it is also known to use optical signal-escaping interconnects. This, however, requires electrical-to-optical and optical-to-electrical conversion, which is more complex than the solution described herein and thus increases both the power consumption and the cost. Moreover, the stringent thermal requirements for lasers and the precision beam alignment requirements (e.g. often limited to only a few micrometers of tolerance) can also pose additional technical problems in real-world implementations.

Advantageously, the WIB solution disclosed herein supports UWB wireless coupling (e.g., 60 GHz bandwidth with fc=140 GHz in mmW bands and/or 230 GHZ bandwidth with fc=415 GHz in THz bands) between the couplers and the WIB.

Moreover, the WIB solution disclosed herein offers relatively flat amplitude and group delay responses of the horizontal waveguide channel between the OAMs over entire operational frequency range. Thus, it does not require many equalizer taps, nor does it necessitate a higher-order impedance matching network. This, in turn, translates to improved system efficiency (e.g., picojoule per bit, pJ/b).

The WIB solution disclosed herein optionally further leverages a UWB engineered material architecture, which will be referred to herein as the “magic wall”. This magic wall reduces electromagnetic wave propagation through or past a gap between the chip and the removeable waveguide and thus resolves the previously identified challenges with respect to signal leakage/isolation.

In addition, the WIB module as disclosed herein may be formed with a plurality of WIBs in a WIB array. This array architecture is both vertically and horizontally scalable without losing the pseudo-independence of its channel capability.

The WIB module as disclosed herein further relaxes mechanical-alignment tolerance requirements, which greatly simplifies manufacture and real-world implementation. In many instances, the tolerance requirement can be, for example, fewer than a couple hundred micrometers for D band case, 110-170 GHz, compared to the above-referenced and more-restrictive tolerance requirements of the optical signal-escape interconnect (e.g., perhaps fewer than 10 μm for single mode operation).

The WIB module further allows for an easier OAM interconnect-escape (e.g., a lower pin count), compared to conventional copper-based interconnects. This further alleviates package/PCB routing congestion and can even reduce the package/PCB layer count. Taken together, the WIB solution reduces impact on system flexibility and reliability. As stated above, the shorter transmission path that results from the WIB-solution also results in lower latency.

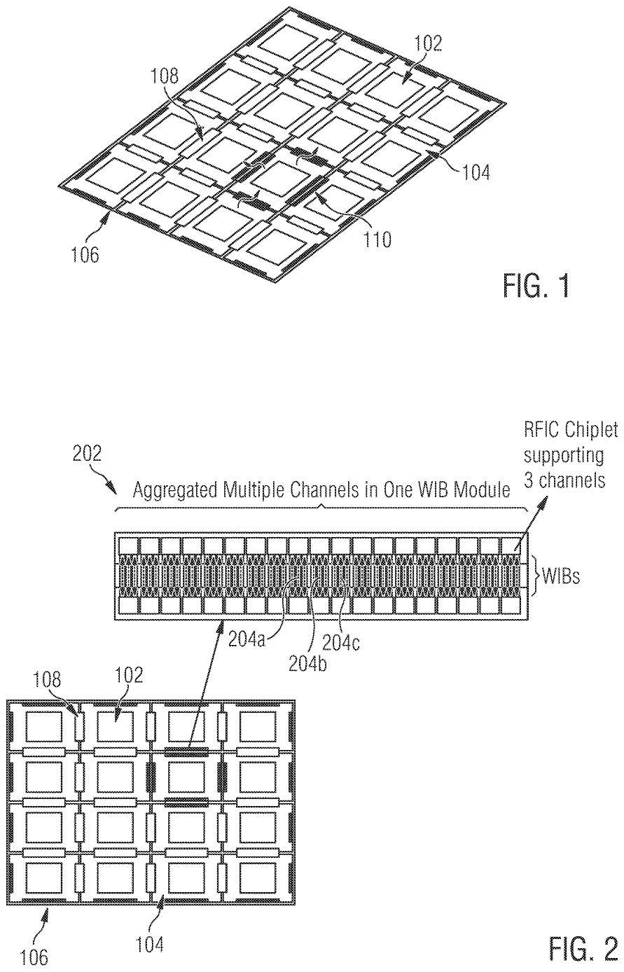

A multichip (e.g. multichiplet) configuration with chip-to-chip connections via WIB is depicted in FIG. 1. In this figure, a die complex including multiple chiplets 102 is depicted. This multichip configuration is illustratively depicted according to the OAM configuration in which the chiplets are mounted on substrates 104 of 140×98 mm², with 5 mm spacing between, although the removeable WIB configuration disclosed herein may be applied to other configurations and/or multichip systems with other dimensions. The various substrates of 104 may be mounted on a common baseboard 106, such as a UBB. The various substrates (e.g. the chips of the various substrates) may be connected to neighboring substates (e.g. to chips of neighboring substrates) via a removable WIB 108. In this manner, a single chip may enjoy multiple channels 110 (see four waveguides surrounding single chip).

FIG. 2 depicts an optional aggregated multiple channel arrangement in a WIB array 202. A WIB waveguide may be configured as part of a WIB array. The WIB module may include a plurality of WIB channel links 204a, 204b, 204c, (which may be referred to herein as a waveguide array), arranged in parallel, such that a single chip may transmit to a neighboring chip along any of multiple channels. Since these channels (e.g. the channels as defined by the waveguides) exhibit a high degree of isolation from neighboring channels, such transmissions may occur with minimal interference from other channels.

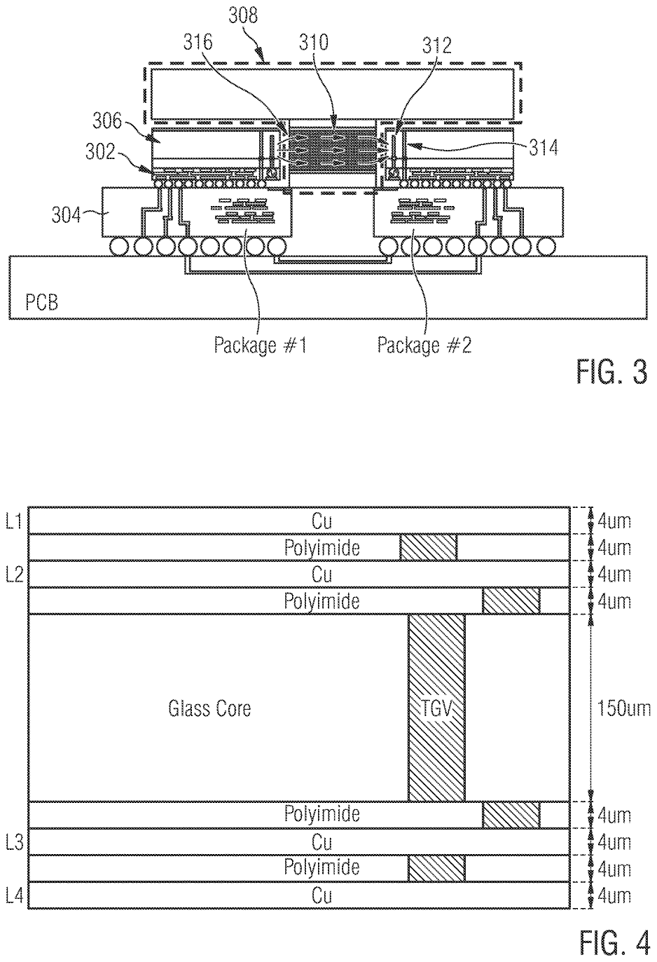

FIG. 3 is a cross-section of a waveguide of FIG. 2. In this figure, a first chiplet 302 is on a first package 304, and a second chiplet (not labeled) is on a second package (not labeled). The chiplets may each be disposed on or in a glass core 306 (a glass core is recited as an exemplary material; however, the core need not be made of glass and may include or be composed of plastic, resin, or any of a variety of other materials). The two chiplets may be connected via a removable waveguide module 308, which includes one or more waveguides (a single waveguide is depicted as 310). Each chiplet/core includes an antenna 312, which may be optionally configured as a driven via (e.g. a through glass via). In this manner, the antenna may be electrically conductively connected to a transmitter or transceiver, which may send a wireless signal, such as by controlling a voltage applied at the antenna. Depending on the configuration, the portion labels as 306 may include a glass layer (upper portion of 302) and a silicon layer (darker horizontal portion of 302); in such circumstances, the through glass via may be connected to a through silicon via. In some configurations, the darker horizontal portion of 306 may be a redistribution layer; in this case, the through glass via may be connected to a microvia in the redistribution layer. The package may further optionally include one or more reflector vias 314 (e.g. a through glass via), which may be connected to a reference voltage (e.g. a ground, a virtual ground, etc.), and may be configured to reflect electromagnetic waves emitted from the antenna into the waveguide. The waveguide may be contactless, in the sense that the waveguide may be configured not to abut a lateral edge of the core-that is, the waveguide may be placed relative to the core such that a small air gap 316 exists between them.

A significant challenge related to the implementation of a vertically-polarized UWB coupler design results from the multiple boundary conditions inherent in the link. That is, a radiofrequency signal for transmission along the waveguide must undergo transition from a first coupler to air, from air to the WIB (e.g. the waveguide), from the WIB to air, and from air to a second coupler. Each of these transitions is associated with its own impedance variation. Accordingly, any coupler needs to accommodate the low (<50 Ohms) to high (>300 Ohms) impedance variations through the boundaries.

As an illustration of this point, an exemplary glass-based substrate stackup with a 2-channel coupler and a WIB design as depicted in FIG. 4 is considered. The coupler may include conductive and dielectric (non-conductive layers). The conductive layers may be Cu, Al, Au, Ti, Ni, Pt, Pd or similar conductors or compositions, and the dielectric materials may be polyimides, Polybenzoxazoles, SiN, SiOx, or low-k dielectrics. Furthermore each conductive and dielectric layer can be of a different material The coupler and RFIC can optionally be stacked together as a single chiplet (e.g. a non-monolithic die complex), such as by using hybrid bonding, direct bonding, or other methods. Alternatively, two monolithic chiplets, i.e. one is for RFIC and the other for coupler), can be connected through package layers. With a removable waveguide, there is necessarily an air gap between the coupler and the WIB-the air gap, however small, being a consequence of the WIB being able to be removed and/or inserted.

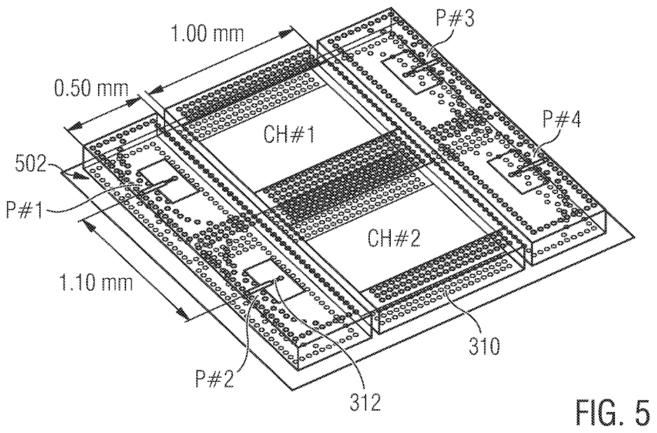

FIG. 5 depicts a 3D View of geometry, channel, and port definitions for the multichip stack with removable waveguide. The dielectric constant of the glass core is assumed as 4.36, although glass with another dielectric constant may be used. This exemplary waveguide module includes a first waveguide channel link 502 and a second waveguide channel link 504. Each waveguide channel link includes a driven via 312 (not connected to a ground), one or more reflector vias 314 (connected to a ground), and a transmission channel as part of the waveguide 310. In this figure, the waveguide channel is depicted as being 1.00 mm long, the transmitter portion of the chiplet that includes the driven via and the one or more reflector vias is depicted as having a length (along the same axis as the length of the waveguide) of 0.50 mm, and each air gap having a length of 0.065 mm. The combined width of the channels is depicted as being 1.23 mm wide. These dimensions are, however, provided for demonstrative purposes only and are not intended to be limiting. An implementation of the removable waveguide may differ from the module of FIG. 5 by any, or any combination of, dimension(s).

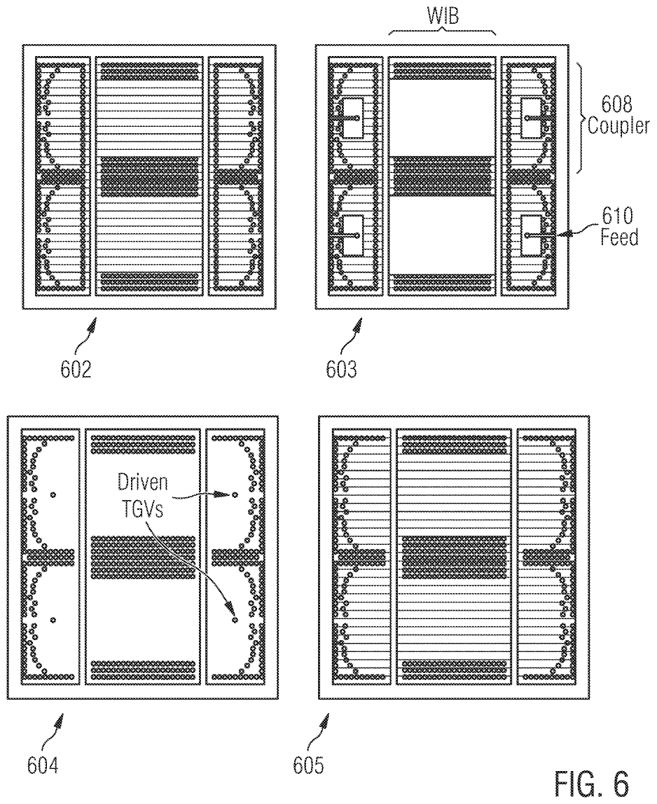

FIG. 6 depicts two re-distribution layers on and below glass core (layer 1 602 and layer 2 603, core vias (TGVs) 604, and layers 3 and 4 605) for 140-GHz dual-channel example. The chips wirelessly communicate with one another using a waveguide 606. The coupler 608 is fed by a co-planar waveguide (CPW) transmission-line 610 and connected to a driven via (e.g. a through glass via (TGV)). In this illustration, there is a large metal void area around the driven via pad (see layer 2 604), which is typically larger than 3× via pad area, which provides broad impedance transition from a coplanar waveguide (CPW) feed to the driven via (see Layer 2). The reflective vias (e.g. ground vias) behind the driven via (see cross-sectional view of glass core substrate 604) act as a reflector. For this, it is noteworthy that these vias are displayed in a mostly parabolic shape, which may aid in generating a directive reflection, although a parabolic shape is not necessary, and alternative shapes may be used as selected for a given implementation.

This parabolic shape, however, may only approximate a parabolic shape, at least because several vias in close proximity to the driven via are placed irregularly in this figure. These vias (e.g. those slightly deviating from the parabolic reflector shape and that are placed in close proximity to the driven via) may mainly act as an impedance transformer, which may help to balance the impedance of the channel. The remaining vias mainly contribute to shape near-field pattern of the coupler. The reflector shape (e.g. the via-reflector) can be optimized through conventional optimization algorithm, such as a genetic algorithm, particle swarm optimization, or a CMA evolution strategy. Note that the reflector shape of the coupler is not necessarily symmetric or mirrored around the coupler feed, which may be appropriate, such as when asymmetry is desirable to further improve channel-channel isolation level. For example, this may be particularly useful if the WIB is not a rectangular shape.

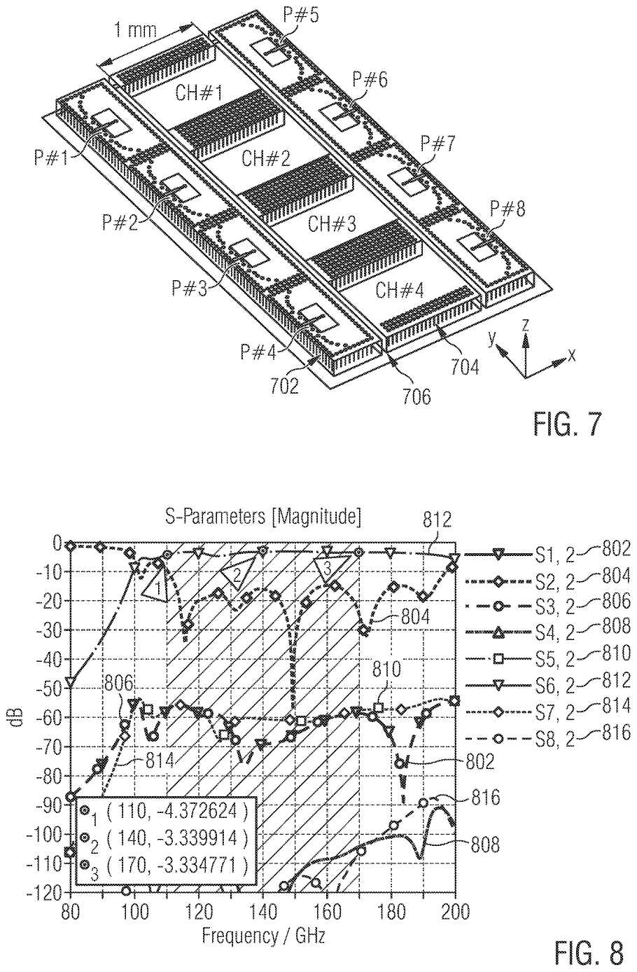

FIG. 7 shows a 4-channel design example, which includes a coupler chiplet 702, and a waveguide 704, wherein the waveguide 704 is placed relative to the chiplet so as to create a gap 706. This gap may be an air gap. Alternatively to the air gap as disclosed herein, the gap between the coupler and the WIB can be optionally filled with an immersion/liquid cooling material. This may require, however, the reflector shape to be optimized to accommodate the different gap material (e.g. to compensate for the different impedance).

Corresponding simulation results for this simulated electric-field distribution at 140 GHz with simultaneous 4-channel excitation and an air gap indicate that each channel is pseudo independent to adjacent channels. Thus, the data throughputs from these channels can be aggregated due to the high isolation (>35 dB) between the channels.

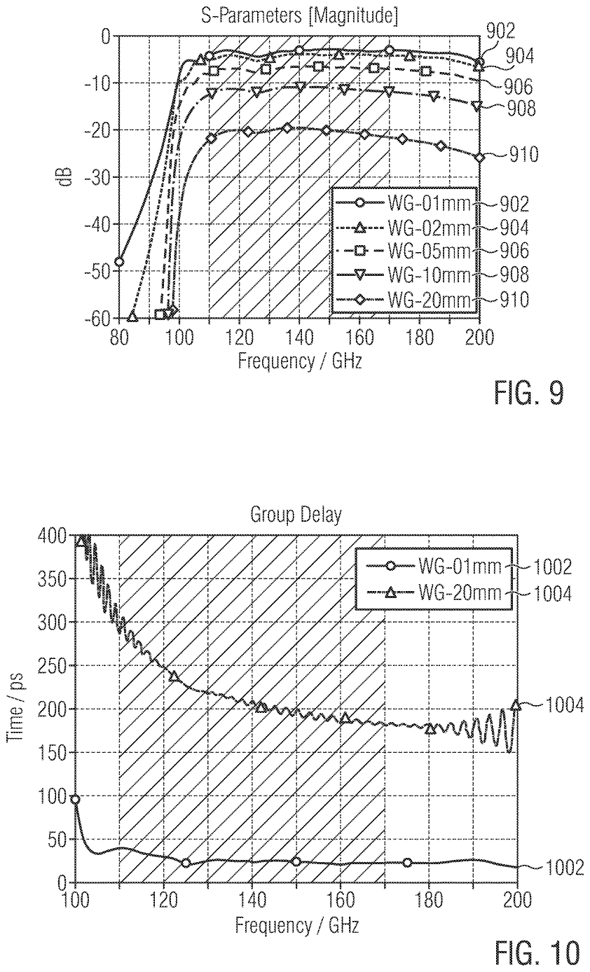

Simulation results for the example 4-channel coupler and WIB design are shown in FIGS. 8-10. In FIG. 8, S-parameters S12-S82 (802, 804, 806, 808, 810, 812, 814, and 816, respectively), are depicted as decibel relative to frequency. In FIG. 9, five S-parameters of WIB channel links for five waveguide lengths (1 mm, 2 mm, 5 mm, 10 mm, and 20 mm, depicted as 902, 904, 906, 908, and 910 respectively) indicate acceptable channel conditions within the waveguide, ranging from approximately −3 dB to approximately −21 dB in the relevant frequency range. FIG. 10 depicts a group delay for a 1 mm waveguide 1002 and for a 20 mm waveguide 1004.

For 1-mm WIB channel length, simulation results show that <5 dB of channel loss, >60 GHz of operational bandwidth, >40 dB of stream-stream isolation, and relatively flat group delay over entire D band (110-170 GHz) with <20 ps variation. The link amplitude results shown in FIG. 9 indicate that the channel length can be extended to more than 20-mm while still satisfying the signal-to-noise ratio (SNR) requirement for 150 Gbps throughput per channel.

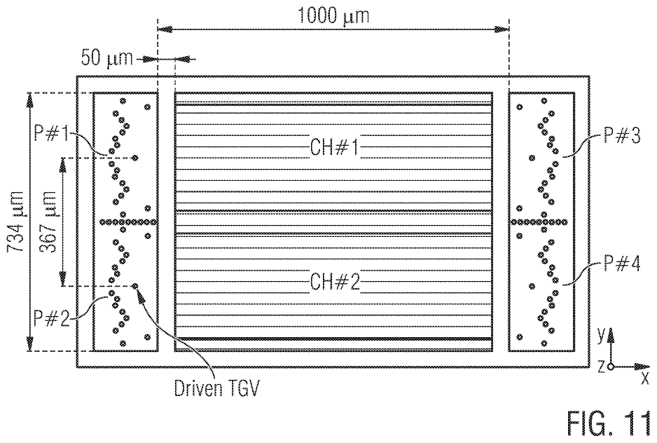

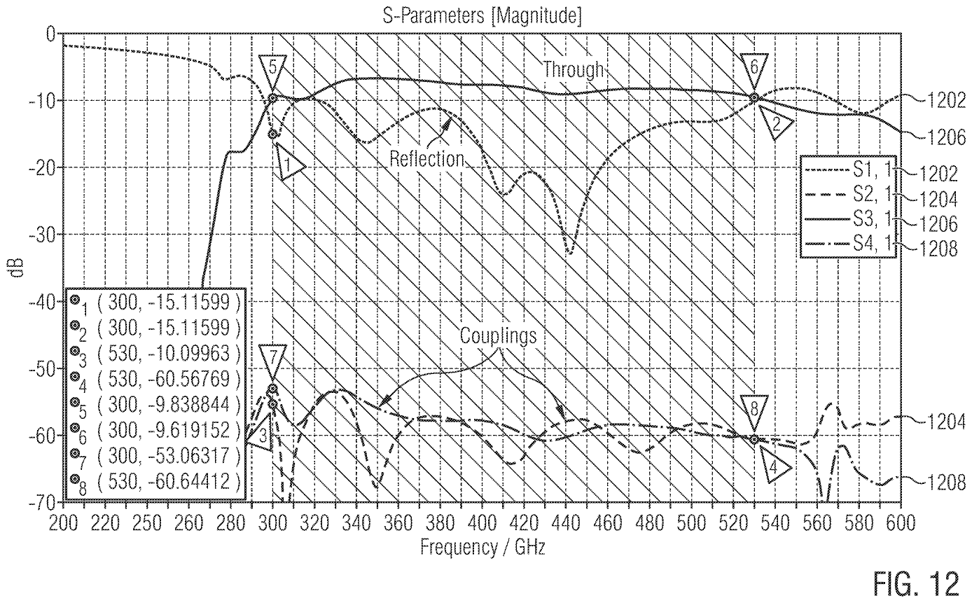

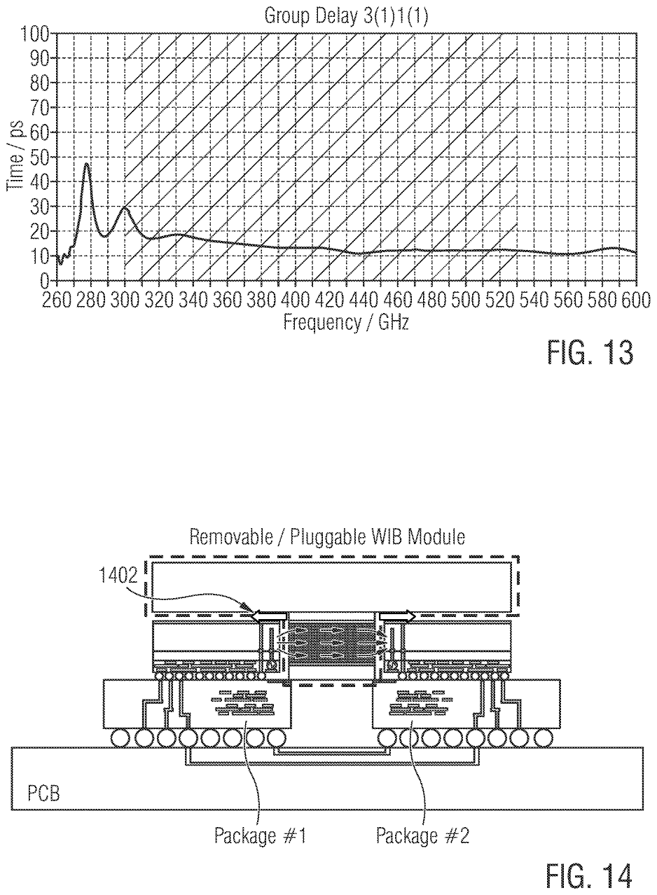

FIG. 11 depicts a coupler and WIB design, which may be particularly useful in supporting a THz band. This design takes into account modern manufacturing capabilities, i.e. an effort to design a realizable, practical coupler and waveguide. In this example, the coupler or WIB pitch is ~367 μm, although other dimensions would be possible. FIGS. 12 and 13 depict performance simulation results of the coupler and WIB design of FIG. 11. In FIG. 12, the S-Parameters for S11, S21, S31, and S41 are depicted as 1202, 1204, 1206, and 1208 respectively. FIG. 13 indicates that the device of FIG. 11 has a relatively flat group delay with <20 ps variation. FIGS. 12 and 13, taken together, show an operational bandwidth of >230 -GHz (300-530 GHZ), >40 dB stream-stream isolation, ~10 dB channel loss, and a relatively flat group delay with <20 ps variation. The theoretical throughput of two channels is estimated as 1.15 Tbps, based on Shannon's Theorem with the assumption of maintaining the same SINR and throughputs with the D-band case.

This THz-band design example (e.g., as shown in FIG. 11) demonstrates that the proposed vertically-polarized (UWB) coupler topology supports easy frequency scale through geometry scale with some modification, and it is versatile and robust due to the simple structural topology. Thus, this structure not only offers scalable solution without using package inner layers to enhance channel-to-channel isolation, but also co-exists with existing wired solutions, e.g. multi-die interconnect bridges and package routing.

When a WIB module is plugged between RFIC-coupler chiplets, there necessarily exists some gap between the WIB module and the top surface of the RFIC-coupler chiplets. FIG. 14 depicts a chip-to-chip waveguide interconnection with a resulting gap 1402. A problem with this gap is that radio signals may leak into it (e.g. leak into adjacent channels). Given manufacturing tolerances, this gap 1402 could be 50 μm or more. In mm Wave or higher frequency ranges, electromagnetic (EM) waves from the coupler will leak into adjacent channels, which results in limitations of data throughput aggregation through the multiple channels. A simulation for such a 2-channel example demonstrated a significantly increased coupling level (~40 dB increase), which means that each channel is not pseudo-independent, due to this leakage. The EM leakage also negatively impacts the flatness of the channel amplitude response over the operational frequency range.

To counteract (e.g. to reduce, to inhibit) this leakage, a unit cell array of engineered material may be placed on the WIB module (or on RFIC-coupler chiplet), so as to create an invisible wall (e.g., a “magic wall”) in air/dielectric gap between the WIB module and the top surface of the RFIC-coupler chiplets. The invisible wall blocks electromagnetic propagation inside the gap while allowing thermal flow of air/fluid cooling of OAM-based hardware acceleration system.

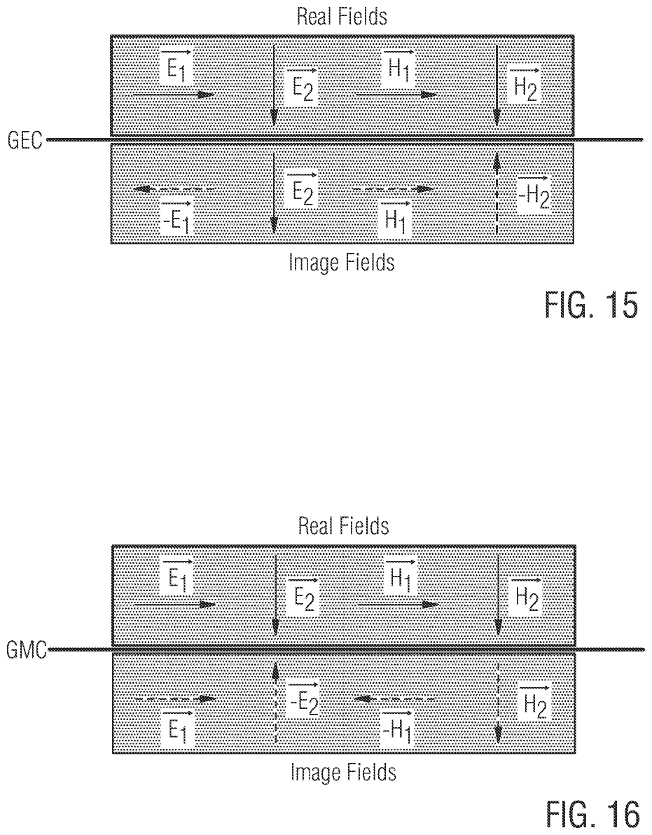

To illustrate how the magic wall works, consider vector electromagnetic fields on a good electric conductor (GEC) in FIG. 15 and vector electromagnetic fields on a good magnetic conductor (GMC) in FIG. 16. For each figure, the corresponding fictitious image fields are depicted as well below the GEC and GMC. In FIG. 15, it can be seen that the electric fields parallel to GEC and that magnetic fields perpendicular to GEC are cancelled out. Similarly, FIG. 16 depicts vector electromagnetic fields on a good magnetic conductor (GMC). As with the previous figure, these are depicted along with their image fields below GMC. As can be seen in FIG. 16, magnetic fields parallel to the GMC and electric fields perpendicular to GMC are cancelled out. This can be understood as the GMC and the GEC being in a dual relationship with respect to the electric field and magnetic field.

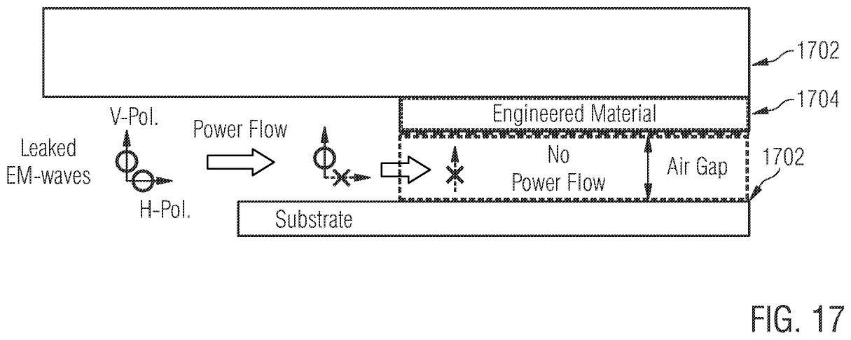

Although GMCs do not exist in nature, engineered material using unit cells can mimic GMC properties. A new leakage-blocking architecture using the magic wall technology is shown in FIG. 17. In this figure, the GEC is depicted as 1702, and the GMC is depicted as 1704. Although the UWB coupler is vertically polarized, some cross-polarization components can be generated when the leaked EM waves reach the gap between the WIB module and the top surface of the RFIC-coupler chiplet. At the opening of this gap, minor horizontal-polarization components of the leaked EM waves are blocked first and then the major vertical-polarization components are blocked by the invisible magic wall formed by the engineered material.

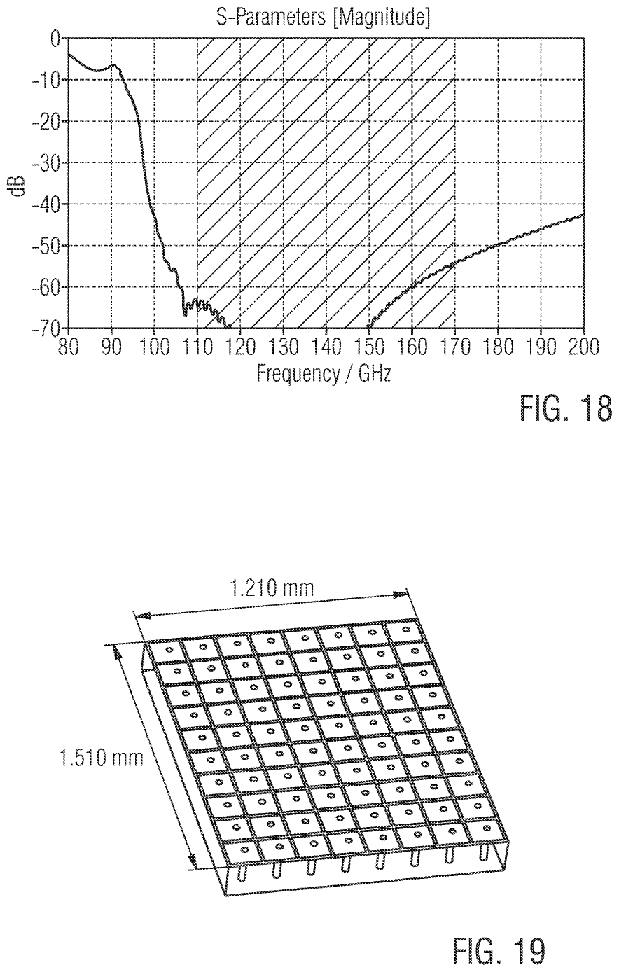

FIG. 18 depicts a simulated performance of a glass-based engineered material deign. This figure depicts a >50 dB EM-wave suppression over the entire D band range (110-170 GHz). When the designed engineered material is attached on the WIB, the simulation results in FIG. 18 show improvement in blocking the propagation of the leaked EM waves in the gap compared with simulations in which unblocked (e.g. not using the magic wall) electromagnetic leakage occurred.

FIG. 19 depicts a good magnetic conductor (GMC) for use in the magic wall construction, disclosed herein. This GMC includes an engineered material having very wide bandwidth, generally of >60 GHz. In this example, the GMC includes a plurality of tiles with ground TGVs on a 1.210 mm by 1.510 mm grid, although other sizes are obviously possible. Each rectangular/square tile, i.e. unit cell, is electrically shorted to a large ground (in this case 1.210 mm×1.510 mm grid) using a TGV. The more unit cells, the higher the suppression level.

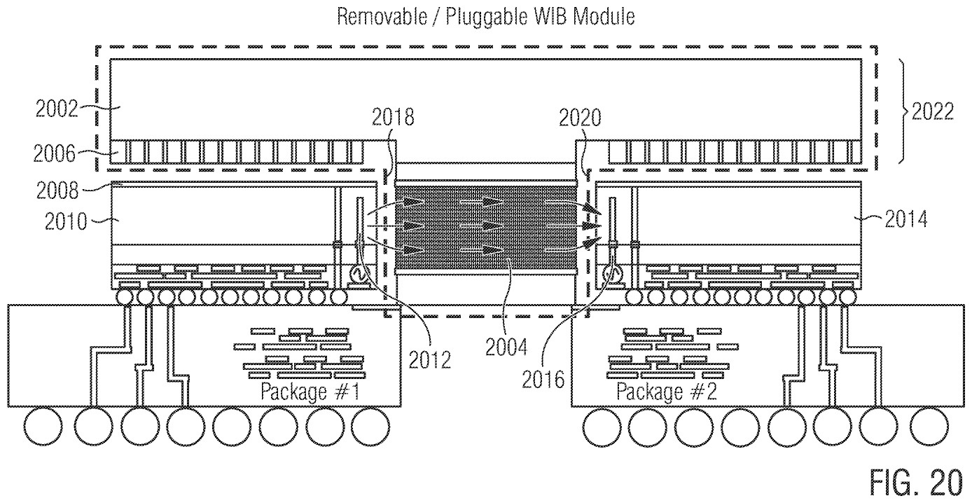

FIG. 20 depicts a chip-to-chip connection with a removable waveguide module 2002. The removable waveguide module may include a substrate (e.g. top, horizontal portion of 2002) and the waveguide 2004, such that the waveguide may be “plugged” into the channel between the two chips as needed. In one configuration, the underside of the substrate (e.g. top portion of 2002) may include a GMC 2006 and the top portion 2008 of the chip may include a GEC. Of course, the placement of the GMC and the GEC may optionally be reversed, such that the GMC is placed on the top portion 2008 of the chip, and the GEC is placed on the underside of the substrate.

Further regarding FIG. 20, this figure depicts a wireless chip-to-chip device with removable waveguide module 2002, including a first substrate 2010 including a first antenna 2012; a second substrate 2014 including a second antenna 2016; and the removable waveguide module 2002, including a waveguide 2004 that is configured to be removably positioned between the first substrate 2010 and the second substrate 2014 and to direct a radio signal from the first antenna 2012 to the second antenna 2016.

The first substrate 2010 and the waveguide 2004 may be positioned relative to each other to form a first dielectric gap 2018 between the first substrate 2010 and the waveguide 2004 and the second substrate 2014 and the waveguide 2004 are positioned relative to each other to form a second dielectric gap 2020 between the second substrate 2014 and the waveguide 2004. The first dielectric gap 2018 and the second dielectric gap 2020 may be air gaps, or they may be filled with a liquid. The removable waveguide module may further includes a third substrate (the portion of waveguide module 2002 defined as 2022), mounted to the waveguide. The wireless chip-to-chip device may further include a metamaterial 2006 on the third surface. The metamaterial 2006 may be configured to form a surface with effective good magnetic conductor. The metamaterial may include a unit cell array of engineered material including a plurality of unit cells, wherein each cell includes a ground plane with a surface area of a first size, a metal plane parallel to the ground plane with a surface area of a second size smaller than the first size, and the metal plane facing the surface of the second substrate. The wireless chip-to-chip device may further include an electrically conductive material 2008 on the first surface and the second surface.

There exists an inevitable misalignment between couplers and WIB arrays during removal/plugging operation, and this misalignment may limit data-throughput aggregation performance. The vertically-polarized coupler design disclosed herein may be tolerant to mechanical misalignment up to 100 μm. This creates great flexibility compared to conventional options, such as, for example, an optical interconnect, which may have a misalignment tolerance of only a few μm. The alignment may be further improved

These features are to locate the pluggable waveguide bridge in the correct location when inserted. By itself these features are not novel and very widely used. They do not change the positional tolerance needs of the pluggable waveguide. Instead these are features to help achieve the positional tolerance needs of the waveguide.

Some examples are: pin in hole, pin in v-groove, sphere in v-groove (or inverse pyramid), locating pins, locating slots, etc. There could be magnets to help with the positioning as well.

Nevertheless, one can further increase the tolerance for mechanical alignment by increasing the WIB pitch and/or tapering aperture edges of WIB. The WIB pitch increase and WIB aperture edge tapering are in trade-offs between tolerance and shoreline efficiency (Tbps/mm). In other words, the increased WIB pitch for higher mechanical misalignment tolerance results in the decreased shoreline efficiency.

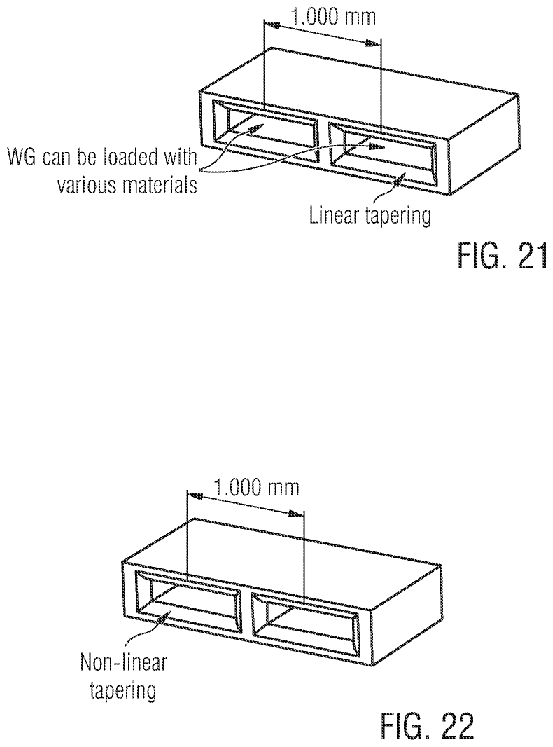

FIGS. 21 and 22 depict WIBs having tapered aperture edges. Specifically, FIG. 21 depicts a WIB having linear tapering at its waveguide opening (e.g. compared to right-angles as depicted elsewhere), and FIG. 22 depicts a WIB having non-linear (e.g. rounded) tapering. As an alternative manufacturing method, a stepped tapering shape can be implemented in re-distribution layers of glass-based WIB. In this manner, the glass-based WIB is generated with stepped or “terrace” tapering, which given the small scale, can approximate a linear or non-linear (e.g. rounded) tapering. Alternatively or additionally, blind vias with various length in glass core can also mimic the stepped tapering shape.

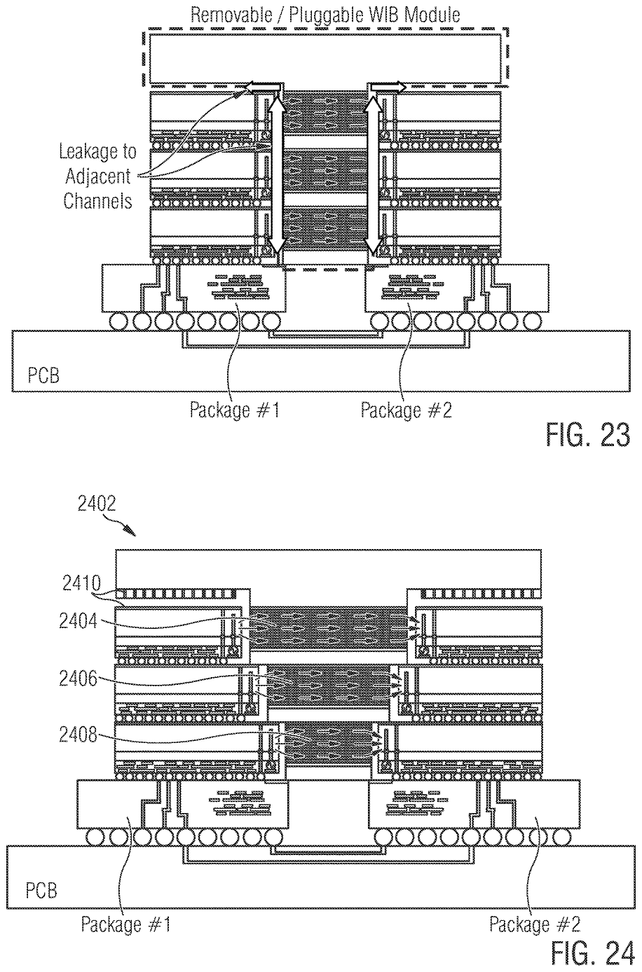

FIG. 23 depicts electromagnetic leakage in vertically stacked chiplets configured to be coupled with a removable waveguide. When RFIC-coupler chiplets are stacked vertically to enable higher aggregated data throughput, leakage may occur in or between vertical channels due to the connected air gaps in the vertical direction. This challenge, which prohibits vertical scalability for data throughput aggregation, can be addressed by the architecture of FIG. 24, which depicts an exemplary waveguide module 2402 that comprises a first waveguide 2404, a second waveguide 2406, and a third waveguide 2408, each waveguide having a different length. Furthermore, this architecture employs the “Magic Wall” 2410, which may limit, minimize, mitigate, or substantially eliminate leakage of electromagnetic waves. The result is enhanced isolation between adjacent channels, compared to the structure in FIG. 23.

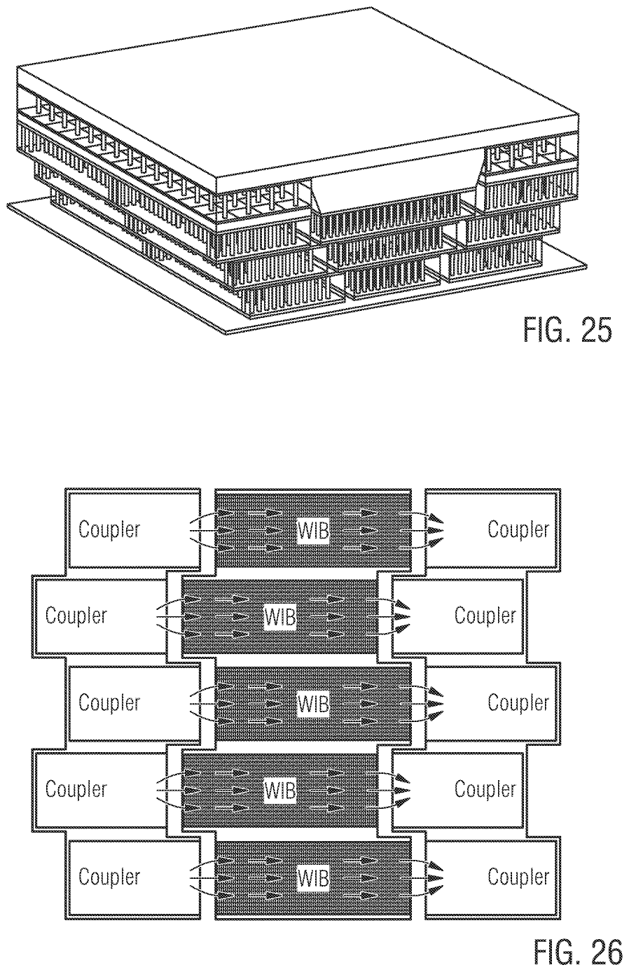

FIG. 25 depicts a stacked-chip interconnection using vertically-stacked removable waveguides. A simulation of this vertically-stacked WIB array demonstrated the effectiveness of the proposed vertical scalability solution. Specifically, the simulation results indicated that all vertically-stacked channels act pseudo independently. Moreover, the simulation results of the 3rd floor channel were very similar to the results of the single-story example with the engineered material-implemented WIB module in FIG. 20. Similarly, The simulation results of the second and first floor channels were similar to the results of the single-story example in FIG. 7 (see FIG. 8 for the results).

FIG. 26 depicts a first configuration for horizontal scalability with a zig-zig alignment, in which each chip-to-chip interconnection using the WIB is laterally offset from the adjacent layer(s), such that a coupler, WIB, and coupler of a first row in FIG. 26 is not directly aligned with a coupler, WIB, and coupler of a second row, but instead the coupler, WIB, and coupler units of each row are shifted horizontally. For clarity, this figure depicts a side-to-side configuration of adjacent waveguide couplers, rather than a vertical stack. With this configuration, a channel (e.g. gap) between adjacent interconnections is eliminated. By employing the “Magic Wall” technique, any residual electromagnetic wave leakage can be greatly reduced, or eliminated altogether. In a horizontal direction (e.g., along an x-y plane, no magic wall may be needed because the proposed geometrical configuration+the UWB antenna/coupler design offer very high isolation. A simulation of the WIB configuration depicted in FIG. 26 evidenced that couplings between channels are extremely low (<−80 dB).

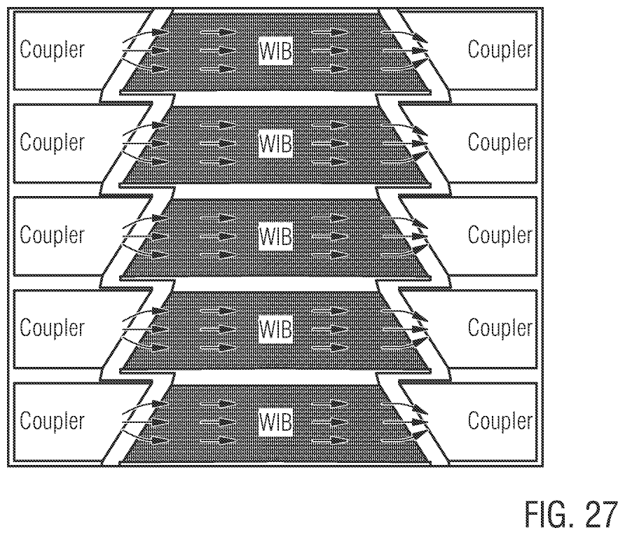

FIG. 27 depicts an alternative to FIG. 26, in which the WIBs are implemented with a trapezoidal shape, and the corresponding couplers have a complementary shape.

The wireless chip-to-chip device may include a removable waveguide module. The wireless chip-to-chip device may further include a first substrate including a first antenna; a second substrate including a second antenna; and the removable waveguide module. The removable waveguide module may include a waveguide that is configured to be removably positioned between the first substrate and the second substrate and to direct a radio signal from the first antenna to the second antenna. Being removably positioned may indicate that it is capable of being removed and reinserted or “plugged in”.

The first substrate and the waveguide may be positioned relative to each other to form a first dielectric gap between the first substrate and the waveguide and the second substrate and the waveguide are positioned relative to each other to form a second dielectric gap between the second substrate and the waveguide. This may be in contrast to a conventional chip to chip waveguide, which may be affixed to the adjacent substrates, such that it is not removable. The dielectric gap insurers removability of the waveguide structure. Depending on the implementation, the first dielectric gap and the second dielectric gap may take different forms. In one configuration, each of the first dielectric gap and the second dielectric gap may be air gaps, such that a small gap between the waveguide and neighboring substrates is filled with air. In another configuration, the first dielectric gap and the second dielectric gap may be filled with a liquid. This liquid may be water, oil, a synthetic material, or any other dielectric liquid desired for the implementation.

In some configurations, the removable waveguide module may further includes a third substrate, mounted to the waveguide. This third substrate is depicted repeatedly herein as a top substrate, wherein the waveguide is mounted to, or otherwise a part of, and underside of the third substrate. In this manner, the third substrate may simplify insertion or removal of the waveguide. Alternatively or additionally, the third substrate may assist in maintaining stability or a stationary positioning of the waveguide once inserted, as the third substrate may rest on top or against the first substrate and the second substrate to be adjoined by the waveguide.

The first substrate may have a first surface, which may be parallel to a longitudinal axis of the first substrate. The first surface may functionally be a top surface or a bottom surface of the first substrate. Similarly, the second substrate may have a second surface, which may be parallel to a longitudinal axis of the second substrate. In this manner, the second surface may functionally be a top surface or a bottom surface of the second substrate. The third substrate may have a third surface, which may be parallel to a longitudinal axis of the third substrate. In this manner, and when the waveguide is positioned between the first substrate and the second substrate, the third surface may be parallel to the first surface and the second surface.

In an alternative configuration, however the waveguide surface may not be parallel, or may not be consistently parallel, with surfaces of the first substrate or second substrate. That is, in a vertical stack, the stack may include a first substrate at a first level, a second substrate at a second level, a third substrate at the first level, and a fourth substrate at the second level. It may be desired, for example, to connect the first substrate at the first level to the fourth substrate at the second level. In this manner, the waveguide may have a curved structure so as to transfer between the first level and the second level. Alternatively, the waveguide may be created with a tapered, terraced, or stepped structure to transfer between the first level and the second level.

The wireless chip-to-chip device may include a metamaterial. This metamaterial may be on the third surface (e.g. on the bottom surface of the substrate on which the waveguide is attached), although the metamaterial may alternatively be on a top side of the first substrate and/or the second substrate. The metamaterial may be configured to form a surface exhibiting good magnetic conduction. That is, the metamaterial may be a good magnetic conductor. The metamaterial may include a unit cell array of engineered material including a plurality of unit cells. In this manner, each cell may include a ground plane with a surface area of a first size, a metal plane parallel to the ground plane with a surface area of a second size smaller than the first size, and having the metal plane face the surface of the second substrate. There may be a via connecting a top metal and bottom ground plane (larger than the top metal plane) in the unit cell. The shorting via reduces the physical size of the unit cell or lowers the suppression band location at frequency. In other words, without this via, the unit cell is too big to provide enough suppression level for a given fixed area. Essentially, the suppression level/area noticeably decreases without the via. The metamaterial may include dielectric material provided between the ground plane and the metal plane. As described herein, the metamaterial may be placed in a gap or space between substrates and/or between a substrate for inter-chip connection and a portion of the waveguide module. The metamaterial, being a good magnetic conductor, may result in magnetic fields parallel to the metamaterial and electric fields perpendicular to the metamaterial being canceled out. In this manner, electromagnetic wave leaking from a gap between a substrate for chip to chip connection and the waveguide may be reduced or canceled.

Similarly, the wireless chip-to-chip device may include an electrically conductive material (also referred to herein as a good electric conductor) on the first surface and the second surface. That is, the electrically conductive material may be present on a surface (e.g. a top surface) of a substrate for connection to a waveguide. As described herein, electric fields parallel to the electrically conductive material and magnetic fields perpendicular to the electrically conductive material are reduced or canceled out.

By combining the good magnetic conductor and the good electric conductor, magnetic fields both parallel and perpendicular to the conductors and electric fields both parallel and perpendicular to the conductors are canceled out. In this manner, electromagnetic wave leakage, such as emanating from a gap between a substrate for chip to chip connection and the waveguide, is reduced, thereby increasing channel isolation.

In some configurations, the metamaterial on the third surface and the electrically conductive material on the first surface and the second surface may be positioned relative to one another to create an air gap between the metamaterial on the third surface and the electrically conductive material on the first surface and the second surface.

Although the good magnetic conductor is generally disclosed herein as being on and underside of the third substrate, and the good electric conductor is generally disclosed herein as being on a top side of the first substrate and the second substrate, these may be reversed, as desired, such that the good magnetic conductor is on the top side of the first substrate and/or the second substrate, and the good electric conductor is on the underside of the third substrate.

In some configurations, a waveguide of the wireless chip-to-chip device may have a fourth surface and a fifth surface, parallel to the fourth surface, wherein the fourth surface and the fifth surface are perpendicular to the third surface; and wherein a junction of the third surface and either the fourth surface or the fifth surface is free from the metamaterial. Otherwise stated, a lateral surface (e.g. a side surface, of the waveguide may lack the meta-material, and a portion of the third surface immediately adjacent to the lateral surface of the waveguide may similarly lack the meta-material. The omission of the meta-material at this location serves a practical purpose by generating a place in which the leaked electromagnetic waves may transfer into the channel (the gap, the space) in which both the good electric conductor and the good magnetic conductor are present.

As described herein, the waveguide may include a tapered opening. The tapered opening may exhibit a linear tapering or a nonlinear (e.g. curved or rounded) tapering. Such tapering may increase a tolerance for placement of the waveguide. That is, given that the waveguide is removable, and therefore that it will be inserted and reinserted into the chip structure, absolute, precise placement of the waveguide (e.g. placement of the waveguide with an extremely small tolerance) is unrealistic. To improve the tolerance, it may be desirable to include a tapered opening, which may enlarge the tolerance to an amount that is reasonably achievable under today's manufacturing standards.

In a multi-waveguide configuration, channel isolation may be of great importance. To that end, various strategies are available to reduce the leakage of electromagnetic waves from one channel to another. One such strategy is to stagger the waveguides (e.g. stagger the waveguides and their corresponding substrates for inter-chip connection) so that an entrance to a waveguide is not immediately below or adjacent to an entrance to a neighboring waveguide. In this manner, a waveguide (which may be understood as a first waveguide) and a second waveguide may be placed within the same chip package, but a length of the second waveguide may be less than a length of the first waveguide. In varying the lengths of the waveguides, the waveguides may assume a triangular or pyramid-like form, or may be staggered or offset with respect to one another. However they are assembled, the offset between the opening of the first waveguide and the opening of the second waveguide inhibits leakage of electromagnetic waves from one channel into a neighboring channel.

Should it, however, be desired to place waveguides of identical length immediately adjacent to one another, an alternative strategy to reduce leakage is to assemble the waveguides in a trapezoidal shape. In this manner, and opening of a first waveguide is not immediately adjacent to a gap in which electromagnetic waves may leak from one channel into another. As such, inter-channel leakage may be reduced.

The first substrate and the second substrate as disclosed herein may be optionally configured as glass core substrates. Such glass core substrates may optionally include borosilicate glass and/or fused silica and may be fashioned to include through-glass vias, as desired. Nevertheless, and although glass core substrates may offer a number of advantages in chiplet-to-chiplet interconnections, the use of glass core substrates is only one possibility and other materials may be used for the substrates as desired.

Whatever the material, the substrates may be configured to include a plurality of through-substrate vias, which may be or include an electrically conductive material essentially perpendicular to a longitudinal access of the substrate. As described herein, and with respect to the chip to chip communication, at least one via in each of a transmitting and receiving substrate may be a driven via, which may be electrically conductively connected to a transmitter or receiver, such that the driven via functions as an antenna. The substrates (e.g. the first substrate and the second substrate) may each include one or more additional vias, which may function as a reflector. These one or more additional vias may be connected to a reference voltage (e.g. a ground voltage) and may functionally reflect a transmission from a driven via into the waveguide or a transmission from a waveguide toward a driven via. As disclosed herein, the patterns of these reflective vias may additionally be selected to alter and/or balance impedance.

Each of the first substrate and the second substrate may optionally include a duplexer. Such duplexer may permit the substrates (substrate and driven antennas as disclosed herein) to establish a bi-directional link.

The first substrate and the second substrate may be part of the same package or of different packages. That is, the waveguide as disclosed herein may be configured to connect chips that are part of the same package, and/or the waveguide as disclosed herein may be configured to connect chips that are part of the different packages. Nothing about the use of the term “substrate” is intended to limit the implementation of the removeable waveguide structure to chips in either a common package or in different packages.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

Further aspects of the disclosure will be shown by way of example:

In Example 1, a wireless chip-to-chip device with removable waveguide module, including: a first substrate including a first antenna; a second substrate including a second antenna; and the removable waveguide module, including a waveguide that is configured to be removably positioned between the first substrate and the second substrate and to direct a radio signal from the first antenna to the second antenna.

In Example 2, the wireless chip-to-chip device of claim 1, wherein the first substrate and the waveguide are positioned relative to each other to form a first dielectric gap between the first substrate and the waveguide and the second substrate and the waveguide are positioned relative to each other to form a second dielectric gap between the second substrate and the waveguide.

In Example 3, the wireless chip-to-chip device of claim 2, wherein the first dielectric gap and the second dielectric gaps are air gaps.

In Example 4, the wireless chip-to-chip device of claim 2, wherein the first dielectric gap and the second dielectric gaps are filled with a liquid.

In Example 5, the wireless chip-to-chip device of any one of claims 1 to 4, wherein the removable waveguide module further includes a third substrate, mounted to the waveguide.

In Example 6, the wireless chip-to-chip device of claim 5, wherein the first substrate has a first surface, parallel to a longitudinal axis of the first substrate; wherein the second substrate has a second surface, parallel to a longitudinal axis of the second substrate; wherein the third substrate has a third surface, parallel to a longitudinal axis of the third substrate; and wherein when the waveguide is positioned between the first substrate and the second substrate, the third surface is parallel to the first surface and the second surface.

In Example 7, the wireless chip-to-chip device of claim 6, further including a metamaterial on the third surface.

In Example 8, the wireless chip-to-chip device of claim 7, wherein the metamaterial is configured to form a surface with effective good magnetic conductor.

In Example 9, the wireless chip-to-chip device of claim 8, wherein the metamaterial includes a unit cell array of engineered material including a plurality of unit cells; wherein each cell includes a ground plane with a surface area of a first size, a metal plane parallel to the ground plane with a surface area of a second size smaller than the first size, and the metal plane facing the surface of the second substrate; further including dielectric material provided between the ground plane and the metal plane.

In Example 10, the wireless chip-to-chip device of any one of claims 6 to 9, further including an electrically conductive material on the first surface and the second surface.

In Example 11, the wireless chip-to-chip device of claim 10, wherein the metamaterial on the third surface and the electrically conductive material on the first surface and the second surface are positioned relative to one another to create an air gap between the metamaterial on the third surface and the electrically conductive material on the first surface and the second surface.

In Example 12, the wireless chip-to-chip device of any one of claims 7 to 11:

wherein the waveguide has a fourth surface and a fifth surface, parallel to the fourth surface, wherein the fourth surface and the fifth surface are perpendicular to the third surface; and wherein a junction of the third surface and either the fourth surface or the fifth surface is free from the metamaterial.

In Example 13, the wireless chip-to-chip device of any one of claims 1 to 12, wherein the waveguide includes a tapered opening.

In Example 14, the wireless chip-to-chip device of any one of claims 1 to 13, wherein the waveguide is a first waveguide; further including a second waveguide, wherein a length of the second waveguide is less than a length of the first waveguide.

In Example 15, the wireless chip-to-chip device of any one of claims 1 to 13, wherein the waveguide is a first waveguide; further including a second waveguide, wherein the first waveguide is laterally offset relative to the second waveguide.

In Example 16, the wireless chip-to-chip device of any one of claims 1 to 13, wherein the waveguide is a first waveguide; further including a second waveguide; wherein a top surface, a bottom surface, a left side, and a right side of the first waveguide form a trapezoidal shape; and wherein a top surface, a bottom surface, a left side, and a right side of the second waveguide form a trapezoidal shape.

In Example 17, the wireless chip-to-chip device of any one of claims 1 to 16, wherein the first substrate includes a glass core, and wherein the second substrate includes a glass core.

In Example 18, the wireless chip-to-chip device of any one of claims 1 to 17, wherein the first substrate further includes a first plurality of vias, connected to a reference voltage and configured to reflect the radio signal emitted from the first antenna; and wherein the second substrate further includes a second plurality of vias, connected to a reference voltage, and configured to reflect the radio signal emitted to the second antenna.

In Example 19, the wireless chip-to-chip device of claim 18, wherein the first plurality of vias and the second plurality of vias are arranged in a parabolic shape.

In Example 20, a wireless chip-to-chip device with removable waveguide, including: a first substrate including a first antenna, for emitting or receiving a radio signal; a second substrate including a second antenna, for receiving or emitting the radio signal; and a removable waveguide module, for being removably positioned between the first substrate and the second substrate, and for directing the radio signal to from the first substrate to the second substrate.

In Example 21, the wireless chip-to-chip device with removable waveguide of claim 20, including: a first substrate including a first duplexer and a second substrate including a second duplexer, for supporting bi-directional link In Example 22, the wireless chip-to-chip device of claim 21, further including metamaterial on the removable waveguide module for reducing a vertical polarization component of an electromagnetic wave leaked from a space between the removable waveguide module and the first substrate or the second substrate.

In Example 23, the wireless chip-to-chip device of any one of claims 20 to 22, further including an electrically conductive material on the first substrate or the second substrate for reducing a horizontal polarization component of an electromagnetic wave leaked from a space between the removable waveguide module and the first substrate or the second substrate.

In Example 24, a wireless chip-to-chip device with removable waveguide module, including: a first substrate with a first antenna, for sending a radio transmission; a second substrate with a second antenna, for receiving the radio transmission; and a removable waveguide module for being removably positioned between the first substrate and the second substrate and for directing a radio signal from the first antenna to the second antenna.

In Example 25, the wireless chip-to-chip device of claim 24, wherein the first substrate and the waveguide are positioned relative to each other for forming a first dielectric gap between the first substrate and the waveguide and the second substrate and the waveguide are positioned relative to each other for forming a second dielectric gap between the second substrate and the waveguide.

In Example 26, the wireless chip-to-chip device of claim 25, wherein the first dielectric gap and the second dielectric gaps are air gaps.

In Example 27, the wireless chip-to-chip device of claim 25, wherein the first dielectric gap and the second dielectric gaps are filled with a liquid.

In Example 28, the wireless chip-to-chip device of any one of claims 24 to 27, wherein the removable waveguide module further includes a third substrate, mounted to the waveguide, for simplifying insertion or removal of the waveguide.

In Example 29, the wireless chip-to-chip device of claim 28, wherein the first substrate has a first surface, parallel to a longitudinal axis of the first substrate; wherein the second substrate has a second surface, parallel to a longitudinal axis of the second substrate; wherein the third substrate has a third surface, parallel to a longitudinal axis of the third substrate; and wherein when the waveguide is positioned between the first substrate and the second substrate, the third surface is parallel to the first surface and the second surface.

In Example 30, the wireless chip-to-chip device of claim 29, further including a metamaterial on the third surface, wherein the metamaterial is for good magnetic conduction.

In Example 31, the wireless chip-to-chip device of claim 30, wherein the metamaterial includes a unit cell array of engineered material including a plurality of unit cells; wherein each cell includes a ground plane with a surface area of a first size, a metal plane parallel to the ground plane with a surface area of a second size smaller than the first size, and the metal plane facing the surface of the second substrate; further including dielectric material provided between the ground plane and the metal plane.

In Example 32, the wireless chip-to-chip device of any one of claims 28 to 31, further including a material for good electric conduction on the first surface and the second surface.

In Example 33, the wireless chip-to-chip device of claim 32, wherein the metamaterial on the third surface and the electrically conductive material on the first surface and the second surface are positioned relative to one another for creating an air gap between the metamaterial on the third surface and the electrically conductive material on the first surface and the second surface.

In Example 34, the wireless chip-to-chip device of any one of claims 29 to 33: wherein the waveguide has a fourth surface and a fifth surface, parallel to the fourth surface, wherein the fourth surface and the fifth surface are perpendicular to the third surface; and wherein a junction of the third surface and either the fourth surface or the fifth surface is free from the metamaterial.

In Example 35, the wireless chip-to-chip device of any one of claims 24 to 34, wherein the waveguide includes a tapered opening for increasing an alignment tolerance of the waveguide.

In Example 36, the wireless chip-to-chip device of any one of claims 24 to 35, wherein the waveguide is a first waveguide; further including a second waveguide, wherein a length of the second waveguide is less than a length of the first waveguide; and wherein the differing lengths of the waveguides are for increasing channel isolation between the two waveguides.

In Example 37, the wireless chip-to-chip device of any one of claims 24 to 35, wherein the waveguide is a first waveguide; further including a second waveguide, wherein the first waveguide is laterally offset relative to the second waveguide; and wherein the lateral offset of the waveguides is for increasing channel isolation between the two waveguides

In Example 38, the wireless chip-to-chip device of any one of claims 24 to 35, wherein the waveguide is a first waveguide; further including a second waveguide; wherein a top surface, a bottom surface, a left side, and a right side of the first waveguide form a trapezoidal shape; and wherein a top surface, a bottom surface, a left side, and a right side of the second waveguide form a trapezoidal shape; and wherein the trapezoidal shapes are for increasing channel isolation of the two waveguides.

In Example 39, the wireless chip-to-chip device of any one of claims 24 to 38, wherein the first substrate includes a glass core, and wherein the second substrate includes a glass core.

In Example 40, the wireless chip-to-chip device of any one of claims 24 to 39, wherein the first substrate further includes a first plurality of vias for reflecting a signal from a first antenna into the waveguide; and wherein the second substrate further includes a second plurality of vias for reflecting the signal from the waveguide to a second antenna.

In Example 41, the wireless chip-to-chip device of claim 40, wherein the first plurality of vias and the second plurality of vias are arranged in a parabolic shape.

In Example 42, a method of manufacturing a wireless chip-to-chip device with removable waveguide module, including: providing a first substrate including a first antenna; providing a second substrate including a second antenna; and providing the removable waveguide module, including a waveguide that is configured to be removably positioned between the first substrate and the second substrate and to direct a radio signal from the first antenna to the second antenna.

In Example 43, the method of claim 42, including positioning the first substrate and the waveguide relative to each other to form a first dielectric gap between the first substrate and the waveguide and positioning the second substrate and the waveguide relative to each other to form a second dielectric gap between the second substrate and the waveguide.

In Example 44, the method of claim 43, wherein the first dielectric gap and the second dielectric gaps are air gaps.

In Example 45, the method of claim 43, wherein the first dielectric gap and the second dielectric gaps are filled with a liquid.

In Example 46, the method of any one of claims 42 to 45, wherein the removable waveguide module further includes a third substrate, mounted to the waveguide.

In Example 47, the method of claim 46, wherein the first substrate has a first surface, parallel to a longitudinal axis of the first substrate; wherein the second substrate has a second surface, parallel to a longitudinal axis of the second substrate; wherein the third substrate has a third surface, parallel to a longitudinal axis of the third substrate; and wherein when the waveguide is positioned between the first substrate and the second substrate, the third surface is parallel to the first surface and the second surface.

In Example 48, the method of claim 47, further including providing a metamaterial on the third surface.

In Example 49, the method of claim 48, wherein the metamaterial is configured to form a surface with effective good magnetic conductor.

In Example 50, the method of claim 49, wherein the metamaterial includes a unit cell array of engineered material including a plurality of unit cells; wherein each cell includes a ground plane with a surface area of a first size, a metal plane parallel to the ground plane with a surface area of a second size smaller than the first size, and the metal plane facing the surface of the second substrate; further including providing dielectric material between the ground plane and the metal plane.

In Example 51, the method of any one of claims 47 to 50, further including providing an electrically conductive material on the first surface and the second surface.

In Example 52, the method of claim 51, further including positioning the metamaterial on the third surface and the electrically conductive material on the first surface and the second surface relative to one another to create an air gap between the metamaterial on the third surface and the electrically conductive material on the first surface and the second surface.

In Example 53, the method of any one of claims 48 to 52: wherein the waveguide has a fourth surface and a fifth surface, parallel to the fourth surface, wherein the fourth surface and the fifth surface are perpendicular to the third surface; and wherein a junction of the third surface and either the fourth surface or the fifth surface is free from the metamaterial.

In Example 54, the method of any one of claims 42 to 53, further including forming the waveguide with a tapered opening.

In Example 55, the method of any one of claims 42 to 54, wherein the waveguide is a first waveguide; further including a second waveguide, wherein a length of the second waveguide is less than a length of the first waveguide.

In Example 56, the method of any one of claims 42 to 54, wherein the waveguide is a first waveguide; further including providing a second waveguide laterally offset relative to the first waveguide.

In Example 57, the method of any one of claims 42 to 54, further including forming the waveguide in a trapezoidal shape.

In Example 58, the method of any one of claims 42 to 57, further including forming the first substrate with a glass core, and forming the second substrate with a glass core.

In Example 59, the method of any one of claims 42 to 58, further including forming the first substrate to have a first plurality of vias, connected to a reference voltage and configured to reflect the radio signal emitted from the first antenna; and forming the second substrate to have a second plurality of vias, connected to a reference voltage, and configured to reflect the radio signal emitted to the second antenna.

In Example 60, the method of claim 59, further including arranging the first plurality of vias and the second plurality of vias in a parabolic shape.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

1. A wireless chip-to-chip device with removable waveguide, comprising:
a first substrate comprising a first antenna;
a second substrate comprising a second antenna; and
the removable waveguide, wherein the waveguide is configured to be removably disposed between the first substrate and the second substrate and to direct a radio signal from the first antenna to the second antenna.

2. The wireless chip-to-chip device of claim 1, wherein the first substrate and the waveguide are disposed next to each other so as to form a first dielectric gap between the first substrate and the waveguide and the second substrate and the waveguide are positioned next to each other so as to form a second dielectric gap between the second substrate and the waveguide.

3. The wireless chip-to-chip device of claim 2, wherein the first dielectric gap and the second dielectric gaps are air gaps, or wherein the first dielectric gap and the second dielectric gaps are filled with a liquid or non-metallic medium.

4. The wireless chip-to-chip device of claim 1, wherein the removable waveguide is part of a removable waveguide module, and wherein this removable waveguide module comprises a third substrate, mounted to the waveguide;
wherein the first substrate has a first surface, parallel to a longitudinal axis of the first substrate;
wherein the second substrate has a second surface, parallel to a longitudinal axis of the second substrate;
wherein the third substrate has a third surface, parallel to a longitudinal axis of the third substrate; and
wherein when the waveguide is positioned between the first substrate and the second substrate, the third surface is parallel to the first surface and the second surface.

5. The wireless chip-to-chip device of claim 4, further comprising a metamaterial on the third surface.

6. The wireless chip-to-chip device of claim 5, wherein the metamaterial is configured to form a surface with effective good magnetic conductor.

7. The wireless chip-to-chip device of claim 6, wherein the metamaterial comprises a unit cell array of engineered material comprising a plurality of unit cells;
wherein each cell comprises a ground plane with a surface area of a first size, a metal plane parallel to the ground plane with a surface area of a second size smaller than the first size, and the metal plane facing the surface of the second substrate;
further comprising dielectric material provided between the ground plane and the metal plane.

8. The wireless chip-to-chip device of claims 4, further comprising an electrically conductive material on the first surface and the second surface.

9. The wireless chip-to-chip device of claim 8, wherein the metamaterial on the third surface and the electrically conductive material on the first surface and the second surface are positioned relative to one another to create an air gap between the metamaterial on the third surface and the electrically conductive material on the first surface and the second surface.

10. The wireless chip-to-chip device of claim 5:
wherein the waveguide has a fourth surface and a fifth surface, parallel to the fourth surface, wherein the fourth surface and the fifth surface are perpendicular to the third surface; and
wherein a junction of the third surface and either the fourth surface or the fifth surface is free from the metamaterial.

11. The wireless chip-to-chip device of claims 1, wherein the waveguide comprises a tapered opening.

12. The wireless chip-to-chip device of claims 1, wherein the waveguide is a first waveguide;
further comprising a second waveguide, wherein a length of the second waveguide is less than a length of the first waveguide.

13. The wireless chip-to-chip device of claim 1, wherein the waveguide is a first waveguide;
further comprising a second waveguide, wherein the first waveguide is laterally offset relative to the second waveguide.

14. The wireless chip-to-chip device of any one of claim 1, wherein the waveguide is a first waveguide;
further comprising a second waveguide;
wherein a top surface, a bottom surface, a left side, and a right side of the first waveguide form a trapezoidal shape; and
wherein a top surface, a bottom surface, a left side, and a right side of the second waveguide form a trapezoidal shape.

15. The wireless chip-to-chip device of claim 1, wherein the first substrate further comprises a first plurality of vias, connected to a reference voltage and configured to reflect the radio signal emitted from the first antenna; and
wherein the second substrate further comprises a second plurality of vias, connected to a reference voltage, and configured to reflect the radio signal emitted to the second antenna.

16. The wireless chip-to-chip device of claim 15, wherein the first plurality of vias and the second plurality of vias are arranged in a parabolic shape.

17. A wireless chip-to-chip device with removable waveguide, comprising:
a first substrate comprising a first antenna, for emitting or receiving a radio signal;
a second substrate comprising a second antenna, for receiving or emitting the radio signal; and
a removable waveguide, for being removably positioned between the first substrate and the second substrate, and for directing the radio signal to from the first substrate to the second substrate.

18. (canceled)

19. A method of manufacturing a wireless chip-to-chip device with removable waveguide, comprising:
providing a first substrate comprising a first antenna; providing a second substrate comprising a second antenna; and
providing the removable waveguide, comprising a waveguide that is configured to be
removably positioned between the first substrate and the second substrate and to direct a radio signal from the first antenna to the second antenna.

20. The method of claim 19, further comprising positioning the first substrate and the waveguide relative to each other to form a first dielectric gap between the first substrate and the waveguide and positioning the second substrate and the waveguide relative to each other to form a second dielectric gap between the second substrate and the waveguide.
